(19) United States
(12) Patent Application Publication
(10) Pub. No.: US 2011/0102969 A1
(43) Pub. Date: May 5, 2011

(54) MULTILAYER CAPACITOR, MOUNTING STRUCTURE THEREOF, AND METHOD OF MANUFACTURING SAME

(75) Inventor: Masaaki TOGASHI, Tokyo (JP)

(73) Assignee: TDK CORPORATION, TOKYO (JP)

(21) Appl. No.: 12/899,974

(22) Filed: Oct. 7, 2010

(30) Foreign Application Priority Data
Nov. 5, 2009 (JP) 2009-254026

(51) Int. Cl. H01G 4/228; H05K 7/00; H01G 9/00

(52) U.S. Cl. 361/306.3; 361/782; 29/25.03

(57) ABSTRACT

A multilayer capacitor 1 comprises a capacitor element body 2 constituted by a plurality of dielectric layers 10; inner electrodes 3, 4, disposed within the capacitor element body 2, having main electrode parts 31, 41 separated by a distance Wg from third and fourth side faces 2c, 2d; and terminal electrodes 5, 6 disposed on respective end faces 2e, 2f and a part of first to fourth side faces 2a to 2d. The inner electrodes 3, 4 are alternately laminated with the dielectric layer 10. The distance Cv between the inner electrode 3, 4 at the outermost layer on each of the first and second side face 2a, 2b sides and the first or second side face 2a, 2b adjacent to the inner electrode 3, 4 is shorter than the distance Wg between the main electrode part 31, 41 and the third or fourth side face 2c, 2d.

### BACKGROUND OF THE INVENTION

1. Field of the Invention

The present invention relates to a multilayer capacitor in which each of both end faces has a substantially square form, a mounting structure thereof, and a method of manufacturing the same.

2. Related Background Art

A multilayer capacitor has conventionally been known, in which two kinds of inner electrodes formed on different dielectric layers are alternately laminated, so as to form a rectangular parallelepiped element body, while terminal electrodes are provided so as to cover respective end faces of the element body (see, for example, Japanese Patent Application Laid-Open No. 2003-051423). In such a multilayer capacitor, as its size becomes smaller, each end face is made substantially square so that the same mounting structure is obtained when mounted to a circuit board while using any of four side faces of the multilayer capacitor as a mounting surface, whereby the process for mounting the multilayer capacitor can be made efficient.

### SUMMARY OF THE INVENTION

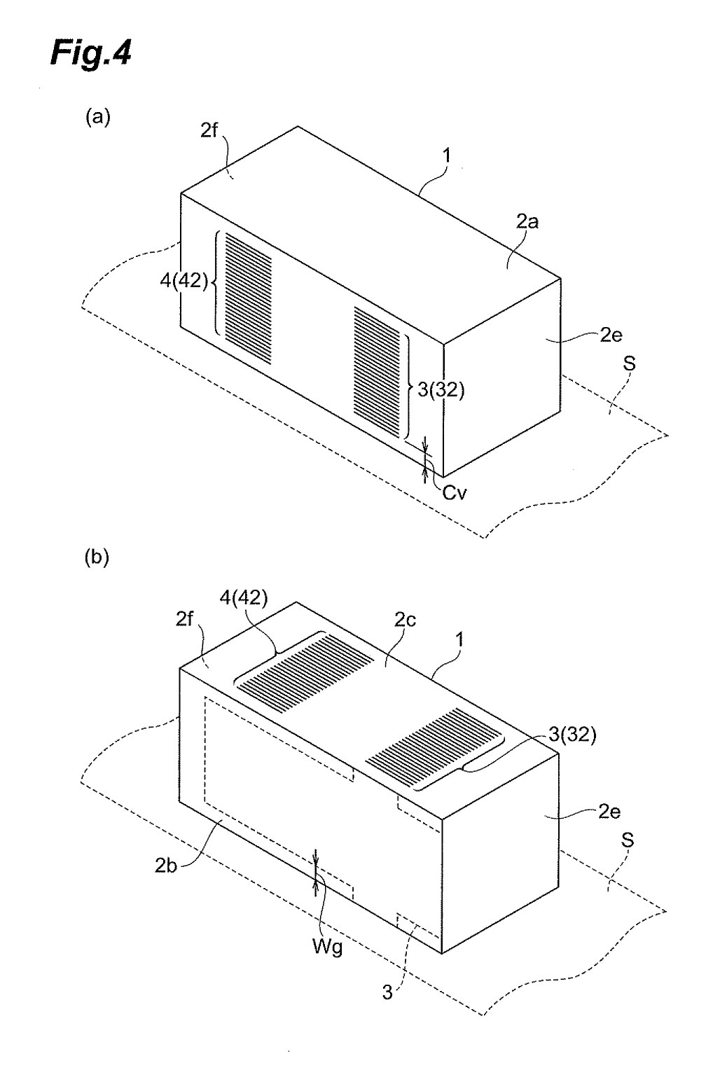

While the same mounting structure in appearance is obtained by the above-mentioned multilayer capacitor using any of its side faces as a mounting surface, the parasitic capacitance occurring between an inner electrode and a circuit board varies depending on whether the mounting direction is such that each inner electrode and the circuit board are parallel to each other (hereinafter also referred to as “horizontal direction”; see FIG. 4(a)) or orthogonal to each other (hereinafter also referred to as “vertical direction”; see FIG. 4(b)) as illustrated in FIG. 4. This has been problematic in that the equivalent series inductance (hereinafter referred to as “ESL”) fluctuates depending on the mounting direction of the multilayer capacitor.

As a result of studies, the inventor has found that, for example, the ESL value of a horizontally mounted multilayer capacitor tends to be higher than that of a vertically mounted multilayer capacitor when the distance Cv between the lowermost inner electrode of the horizontally mounted multilayer capacitor and the circuit board equals the distance Wg between the inner electrode (main electrode part) of the vertically mounted multilayer capacitor and the circuit board. The inventor has further conducted studies about the relationship between the distances Cv, Wg that reduces the fluctuation in ESL value regardless of whether the multilayer capacitor is mounted vertically or horizontally, thereby completing the present invention.

It is an object of the present invention to provide a multilayer capacitor which reduces the fluctuation in ESL value depending on the mounting direction of the multilayer capacitor, a mounting structure of the multilayer capacitor, and a method of manufacturing the multilayer capacitor.

The multilayer capacitor in accordance with the present invention comprises a capacitor element body having first and second side faces, each having a substantially rectangular form, opposing each other, third and fourth side faces extending in a longer side direction of the first and second side faces so as to connect the first and second side faces to each other and opposing each other, and substantially square first and second end faces extending in a shorter side direction of the first and second side faces so as to connect the first and second side faces to each other and opposing each other, the capacitor element body being constituted by a plurality of dielectric layers laminated in the opposing direction of the first and second side faces; a first inner electrode disposed within the capacitor element body, the first inner electrode having a first lead electrode part extending to the third and fourth side faces and a first main electrode part separated by a distance Wg from the third and fourth side faces; a second inner electrode disposed within the capacitor element body, the second inner electrode having a second lead electrode part extending to the third and fourth side faces and a second main electrode part opposing the first main electrode part in the opposing direction of the first and second side faces and separated by the distance Wg from the third and fourth side faces; a first terminal electrode disposed on the first end face side of the first, second, third, and fourth side faces each with an electrode width W1 as a width in the opposing direction of the first and second end faces and connected to the first lead electrode part; and a second terminal electrode disposed on the second end face side of the first, second, third, and fourth side faces each with an electrode width W2 as a width in the opposing direction of the first and second end faces while being separated from the first terminal electrode by a distance G shorter than each of the electrode widths W1 and W2 and connected to the second lead electrode part. The first and second inner electrodes are alternately laminated with a dielectric layer of the plurality of dielectric layers in between in the opposing direction of the first and second side faces, while the first or second inner electrode at the outermost layer on each of the first and second side face sides and the first or second side face adjacent to the inner electrode have a distance Cv therebetween shorter than the distance Wg between the first or second main electrode part and the third or fourth side face.

In the multilayer capacitor in accordance with the present invention, the distance Cv corresponding to the distance between the inner electrode and the circuit board in the case where the mounting direction is such that the inner electrode and the circuit board are parallel to each other is shorter than the distance Wg corresponding to the distance between the inner electrode and the circuit board in the case where the mounting direction is such that the inner electrode and the circuit board intersect. This can reduce the difference between the ESL value generated by the horizontally mounted multilayer capacitor and the ESL value generated by the vertically mounted multilayer capacitor. As a result, the multilayer capacitor in accordance with the present invention can be mounted to a circuit board or the like while using any side face as a mounting surface without taking account of the fluctuation in ESL value and can improve the mounting efficiency. In addition, since the first and second lead electrode parts are constructed so as to extend to the side faces, magnetic fields cancel each other out, whereby low ESL can be obtained.

The “substantially square” form used herein means that one side in the height direction and one side in the width direction have substantially the same length in a predetermined tolerance range so that the same mounting structure can be obtained in terms of design no matter by which side face the multilayer capacitor is mounted to a circuit board. For example, while the vertical and horizontal lengths in the end faces of a size “1005” product have a tolerance of ±0.05 mm with respect to a standard of 0.5 mm, so that the difference between the vertical and horizontal lengths is 22.2% at maximum, such an extent of difference in length is meant to be included.

Preferably, the distances Wg and Cv are set such that a ratio of a first inductance value calculated according to the distance Wg as an equivalent series inductance value obtained when the third or fourth side face of the multilayer capacitor is used as a mounting surface to a second inductance value calculated according to the distance Cv as an equivalent series inductance value obtained when the first or second side face of the multilayer capacitor is used as a mounting surface falls within the range of 0.8 to 1.2. This can further reduce the fluctuation in ESL value.

Preferably, when each side of the first and second end faces has a length of 0.3 to 0.5 mm, the distance Cv is 10 to 40 μm while the distance Wg is 40 to 70 μm. More preferably, the distance Cv is 20 to 30 μm while the distance Wg is 50 to 70 μm. These can further reduce the fluctuation in ESL value. Since the lower limit of the distance Cv is 10 μm, the possibility of cracks caused by stresses exerted on the multilayer capacitor exposing the inner electrodes to the surface is reduced. Since the upper limit of the distance Cv is 40 μm, the number of laminations of inner electrodes in the multilayer capacitor can be increased. Since the lower limit of the distance Wg is 40 μm, the possibility of the main electrode parts being exposed to the side faces because of positional deviations at the time of laminating the inner electrodes can be reduced. Since the upper limit of the distance Wg is 70 μm, the area of the main electrode parts can be increased.

The mounting structure of a multilayer capacitor in accordance with the present invention is a mounting structure for mounting any of the multilayer capacitors mentioned above to a circuit board. The circuit board comprises through-hole electrodes formed in the circuit board so as to be separated from each other by a distance shorter than that between the first and second lead electrode parts in the opposing direction of the first and second end faces, and mounting electrodes formed on the circuit board so as to be connected to the respective through-hole electrodes and extend outward from the through-hole electrodes. Using one of the first, second, third, and fourth side faces as a mounting surface, the first and second terminal electrodes of the multilayer capacitor are connected to the respective mounting electrodes. In this case, a current flowing through the first and second inner electrodes and that flowing through any of the mounting electrodes formed on the circuit board are directed opposite to each other, so that the magnetic fields caused by the respective currents cancel each other out, whereby further lower ESL can be obtained.

The method of manufacturing a multilayer capacitor in accordance with the present invention is a method of manufacturing a multilayer capacitor comprising a capacitor element body having first and second side faces, each having a substantially rectangular form, opposing each other, third and fourth side faces extending in a longer side direction of the first and second side faces so as to connect the first and second side faces to each other and opposing each other, and substantially square first and second end faces extending in a shorter side direction of the first and second side faces so as to connect the first and second side faces to each other and opposing each other; first and second inner electrodes disposed within the capacitor element body; and first and second terminal electrodes disposed on a surface of the capacitor element body. This manufacturing method comprises the steps of forming the first and second inner electrodes on respective dielectric layers; laminating the first and second inner electrodes alternately with a dielectric layer in between, so as to yield a capacitor element body having the first and second inner electrodes arranged therewithin; and forming the first and second terminal electrodes on the capacitor element body. The step of forming the first and second inner electrodes forms the first and second inner electrodes such that the first inner electrode has a first lead electrode part extending to the third and fourth side faces and a first main electrode part separated by a distance Wg from the third and fourth side faces and the second inner electrode has a second lead electrode part extending to the third and fourth side faces and a second main electrode part separated by the distance Wg from the third and fourth side faces. The step of forming the first and second terminal electrodes forms the first terminal electrode disposed on the first end face side of the first, second, third, and fourth side faces each with an electrode width W1 as a width in the opposing direction of the first and second end faces and connected to the first lead electrode part, and the second terminal electrode disposed on the second end face side of the first, second, third, and fourth side faces each with an electrode width W2 as a width in the opposing direction of the first and second end faces while being separated from the first terminal electrode by a distance G shorter than each of the electrode widths W1, W2 and connected to the second lead electrode part. The steps of forming the first and second inner electrodes and yielding the capacitor element body manufacture the multilayer capacitor by laminating the first and second inner electrodes alternately with the dielectric layer in between such that the first or second inner electrode at the outermost layer on each of the first and second side face sides and the first or second side face adjacent to the inner electrode have a distance Cv therebetween shorter than the distance Wg between the first or second main electrode part and the third or fourth side face, and setting the distances Wg and Cv such that a ratio of a first inductance value calculated according to the distance Wg as an equivalent series inductance value obtained when the third or fourth side face of the multilayer capacitor is used as a mounting surface to a second inductance value calculated according to the distance Cv as an equivalent series inductance value obtained when the first or second side face of the multilayer capacitor is used as a mounting surface falls within the range of 0.8 to 1.2. This can manufacture a multilayer capacitor having reduced the fluctuation in ESL mentioned above.

The present invention will become more fully understood from the detailed description given hereinbelow and the accompanying drawings which are given by way of illustration only, and thus are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

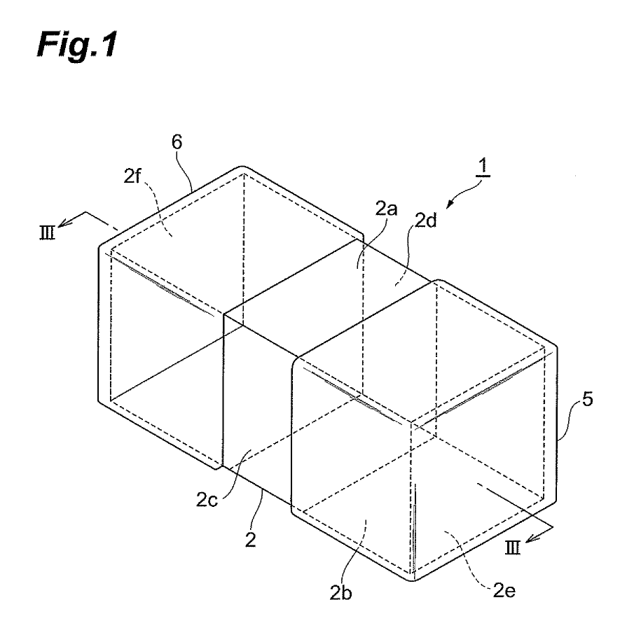

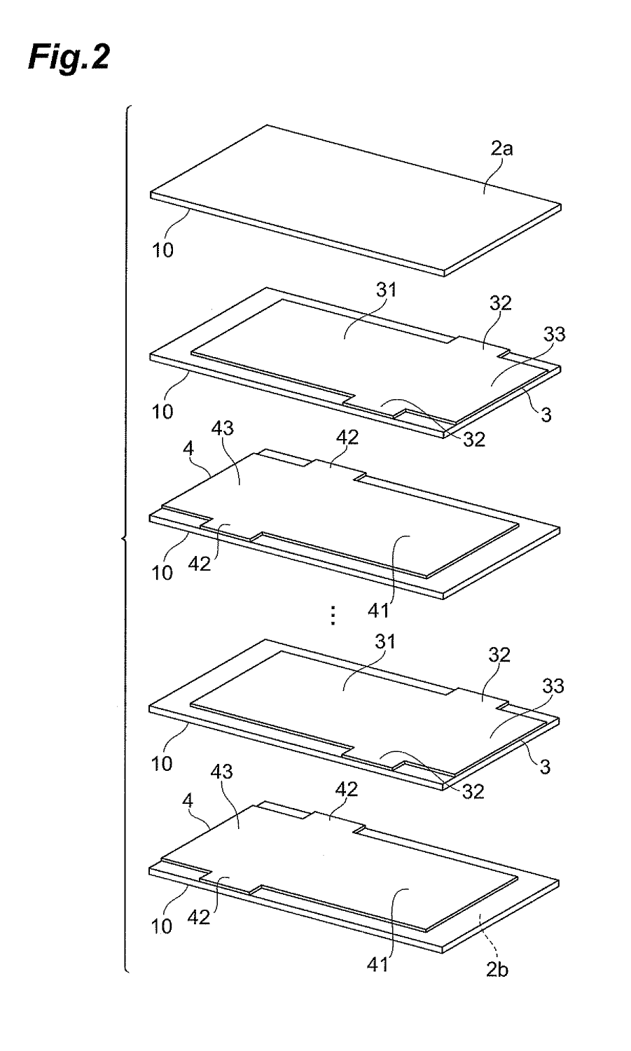

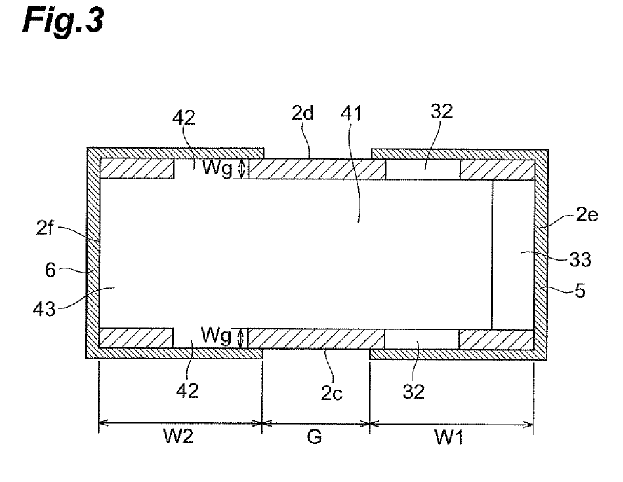

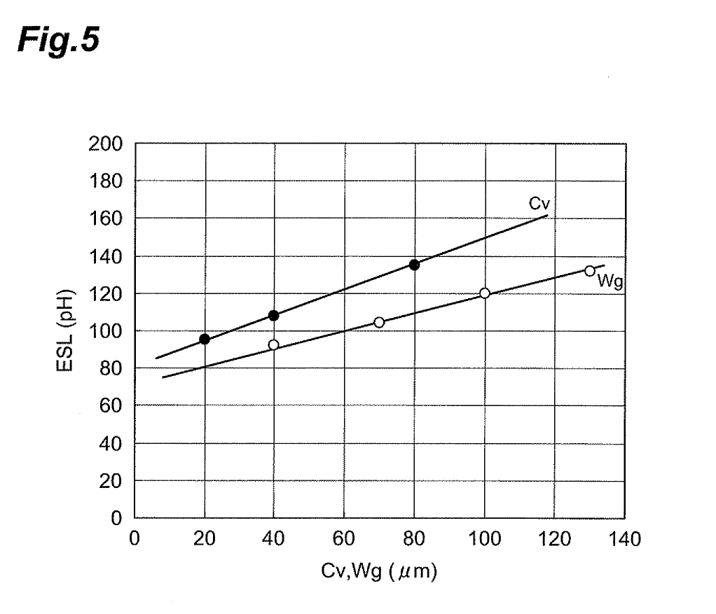

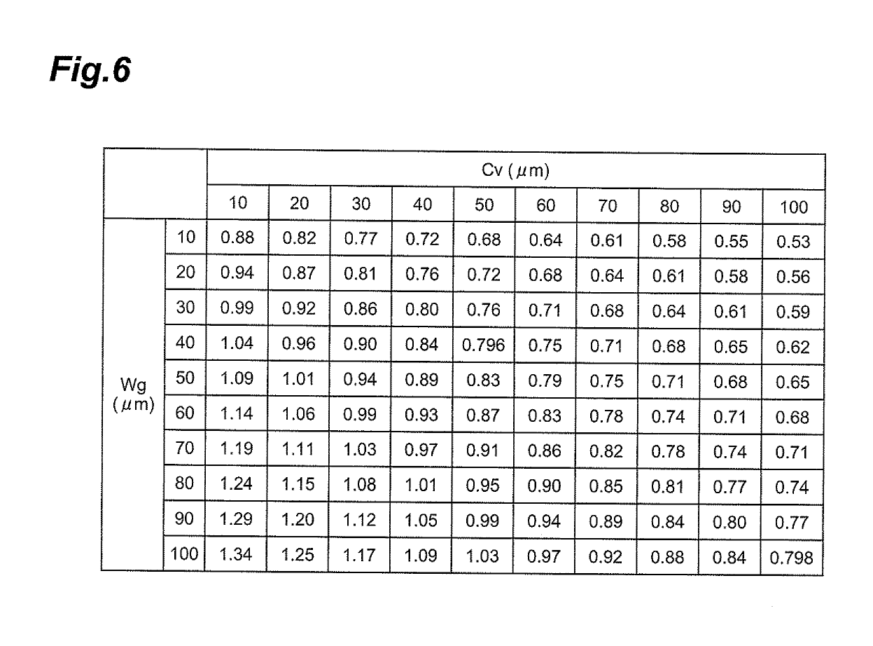

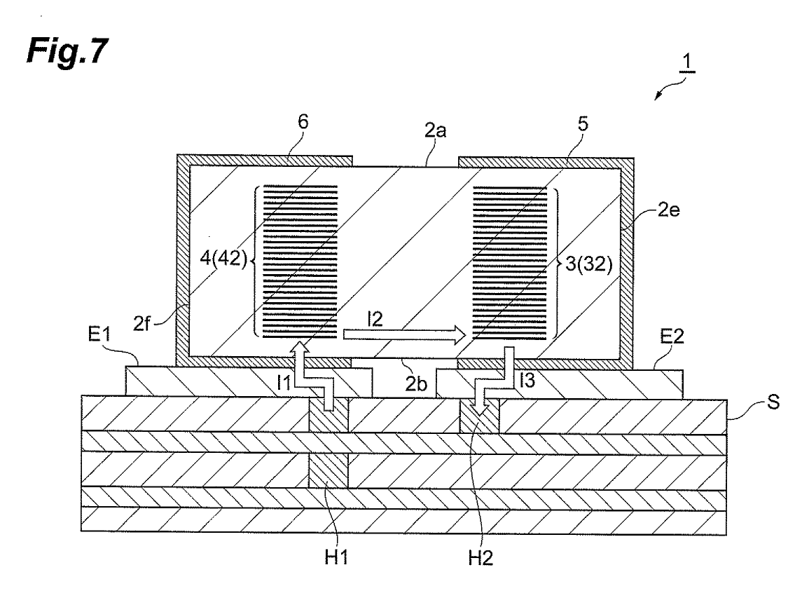

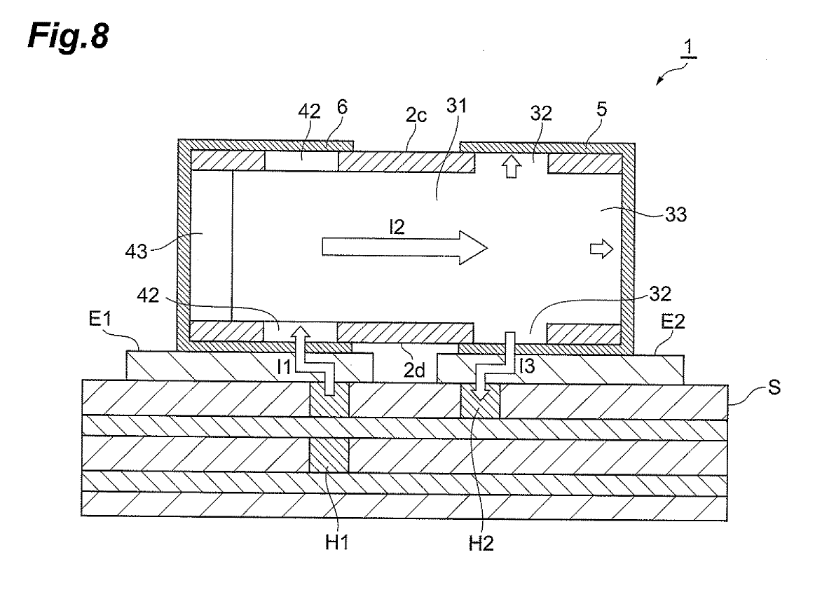

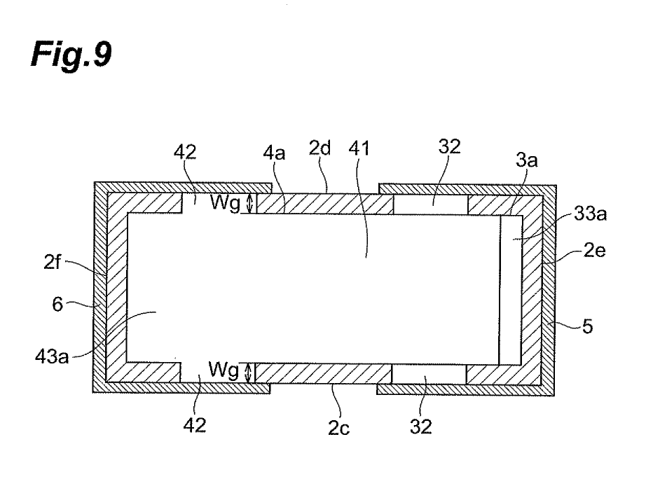

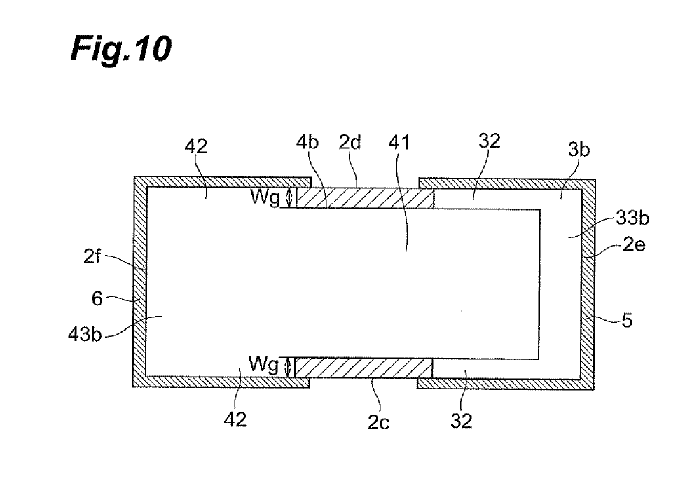

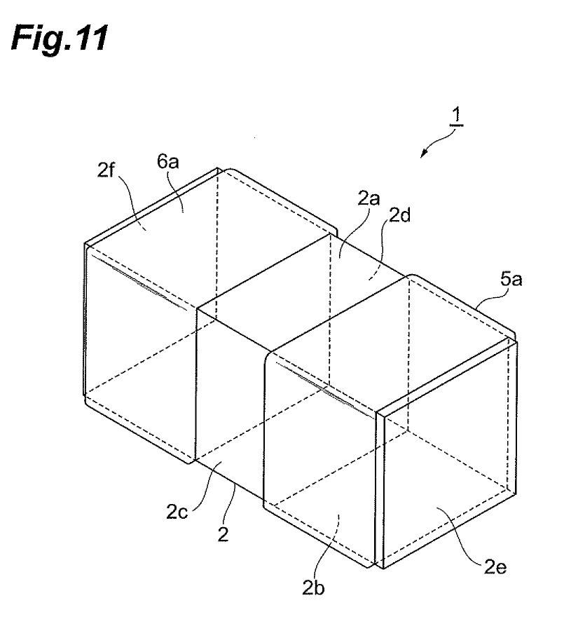

### BRIEF DESCRIPTION OF THE DRAWINGS

[FIG. 1] is a perspective view of a multilayer capacitor;

[FIG. 2] is an exploded perspective view of the multilayer capacitor;

[FIG. 3] is a sectional view taken along the line III-III of FIG. 1;

[FIG. 4](a) and (b) are views illustrating the multilayer capacitor mounted horizontally and vertically, respectively;

[FIG. 5] is a graph illustrating relationships between the distances Cv, Wg of the multilayer capacitor and ESL value;

[FIG. 6] is a chart illustrating relationships between the distances Cv, Wg of the multilayer capacitor and aspect ratio R;

[FIG. 7] is a sectional view illustrating a mounting structure when the multilayer capacitor is mounted horizontally;

[FIG. 8] is a sectional view illustrating a mounting structure when the multilayer capacitor is mounted vertically;

[FIG. 9] is a view illustrating a modified example of inner electrodes;

[FIG. 10] is a view illustrating another modified example of the inner electrodes; and

[FIG. 11] is a view illustrating a modified example of terminal electrodes.

### DESCRIPTION OF THE PREFERRED EMBODIMENTS

In the following, preferred embodiments of the present invention will be explained in detail with reference to the accompanying drawings. In the explanation, the same constituents or those having the same functions will be referred to with the same signs while omitting their overlapping descriptions.

First, with reference to FIGS. 1 to 3, the structure of a multilayer capacitor 1 will be explained. The multilayer capacitor 1 comprises a capacitor element body 2 having a rectangular parallelepiped form, inner electrodes 3, 4 disposed within the capacitor element body 2, and terminal electrodes 5, 6 disposed on outer surfaces of the capacitor element body 2.

The capacitor element body 2 is constituted by a plurality of dielectric layers 10 laminated. The capacitor element body 2 includes substantially rectangular first and second side faces 2a, 2b opposing each other in the laminating direction, substantially rectangular third and fourth side faces 2c, 2d extending in the longer side direction of the first and second side faces 2a, 2b and opposing each other, and substantially square first and second end faces 2e, 2f extending in the shorter side direction of the first and second side faces 2a, 2b and opposing each other. The third and fourth side faces 2c, 2d and the first and second end faces 2e, 2f extend so as to connect the first and second side faces 2a, 2b to each other.

While each of the first and second end faces 2e, 2f has a substantially square form as mentioned above, the “substantially square” form used herein refers to a square whose one side in the height direction and one side in the width direction have substantially the same length in a predetermined tolerance range so that the same mounting structure can be obtained in terms of design no matter by which of the side faces 2a to 2d the multilayer capacitor 1 is mounted to a circuit board. For example, while each of lengths in the end faces of a size “1005” product (multilayer capacitor having a length of 1.0 mm, a height of 0.5 mm, and a width of 0.5 mm) has a tolerance of ±0.05 mm with respect to a standard of 0.5 mm, so that the difference between the lengths is 22.2% at maximum, a form having such an extent of difference in length is also included in the “substantially square” form.

The first terminal electrode 5 is disposed on the surfaces of the capacitor element body 2 so as to cover the parts of the first to fourth side faces 2a to 2d on the first end face 2e side and substantially all of the first end face 2e. Each of the respective parts of the first terminal electrode 5 disposed on the side faces 2a to 2d has an electrode width W1 as a width in the opposing direction of the first and second end faces 2e, 2f (see FIG. 3). The first terminal electrode 5 is connected to the inner electrode 3 (lead electrode parts 32, 33 which will be explained later) on the third and fourth side faces 2c, 2d and the first end face 2e.

The second terminal electrode 6 is disposed on the surfaces of the capacitor element body 2 so as to cover the parts of the first to fourth side faces 2a to 2d on the second end face 2f side and substantially all of the second end face 2f. Each of the respective parts of the second terminal electrode 6 disposed on the side faces 2a to 2d has an electrode width W2 as a width in the opposing direction of the first and second end faces 2e, 2f (see FIG. 3). The second terminal electrode 6 is connected to the inner electrode 4 (lead electrode parts 42, 43 which will be explained later) on the third and fourth side faces 2c, 2d and the second end face 2f.

The first and second terminal electrodes 5 and 6, each having a substantially U-shaped transverse cross section, are arranged so as to oppose each other inward while being separated so as not to connect with each other, their respective inner leading end parts being separated from each other by a distance G. The distance G is set shorter than each of the respective electrode widths W1, W2 of the terminal electrodes 5, 6, so as to reduce the ESL value of the multilayer capacitor 1. Each of the first and second terminal electrodes 5, 6 is made by applying and burning a conductive paste containing a conductive metal powder onto the outer surfaces of the capacitor element body 2. Plating layers may be formed on the surfaces of the burned electrodes when necessary.

As illustrated in FIGS. 2 and 3, first inner electrodes 3 formed on dielectric layers 10 and second inner electrodes 4 formed on other dielectric layers 10 are arranged within the capacitor element body 2. A plurality of first inner electrodes 3 and second inner electrodes 4 are laminated alternately with the dielectric layers 10. Each of the dielectric layers 10 is constituted by a sintered body of a ceramic green sheet containing a dielectric ceramic, for example, while each of the inner electrodes 3, 4 is constituted by a sintered body of a conductive paste. In practice, the multilayer capacitor array 1 is integrated to such an extent that no boundaries between the dielectric layers 10 are discernible.

Each of the first inner electrodes 3 is a substantially rectangular inner electrode. The first inner electrode 3 has a rectangular first main electrode part 31 arranged at a substantially center portion on the dielectric layer 10, first lead electrode parts 32 which are formed continuous with side portions on the first end face 2e side of the first main electrode part 31 and extend to the third and fourth side faces 2c, 2d, respectively, and a third lead electrode part 33 which is formed continuous with the end portion on the first end face 2e side of the first main electrode part 31 and extends to the first end face 2e. The first main electrode part 31 is formed such that its side portions are each separated by a distance Wg from their corresponding third and fourth side faces. The first lead electrode parts 32 drawn to the third and fourth side faces 2c, 2d and the third lead electrode part 33 drawn to the first end face 2e are connected electrically and physically to the first terminal electrode 5 having a width on each of the side faces 2c, 2d and end face 2e greater than the drawn width of each of the lead electrode parts 32, 33.

Each of the second inner electrodes 4 is a substantially rectangular inner electrode. The second inner electrode 4 has a rectangular second main electrode part 41 arranged at a substantially center portion on the other dielectric layer 10, second lead electrode parts 42 which are formed continuous with side portions on the second end face 2f side of the second main electrode part 41 and extend to the third and fourth side faces 2c, 2d, respectively, and a fourth lead electrode part 43 which is formed continuous with the end portion on the second end face 2f side of the second main electrode part 41 and extends to the second end face 2f. As with the first main electrode part 31, the second main electrode part 41 is formed such that its side portions are each separated by the distance Wg from their corresponding third and fourth side faces. The second lead electrode parts 42 drawn to the third and fourth side faces 2c, 2d and the fourth lead electrode part 43 drawn to the second end face 2f are connected electrically and physically to the second terminal electrode 6 having a width on each of the side faces 2e, 2d and end face 2f greater than the drawn width of each of the lead electrode parts 42, 43.

In the opposing direction of the first and second side faces 2a, 2b, the first and second inner electrodes 3, 4 are laminated alternately with a dielectric layer 10 of a plurality of dielectric layers 10 in between. This lamination makes the first and second main electrode parts 31, 41 oppose each other in the opposing direction of the first and second side faces 2a, 2b, thereby constructing a capacitance part of the multilayer capacitor 1. Since each set of the first lead electrode parts 32 and each set of the second lead electrode parts 42 are constructed so as to extend to the third and fourth side faces 2c, 2d, respective currents flowing through the lead electrode parts 32, 42 are directed opposite to each other, so that their magnetic fields cancel each other out, whereby the ESL of the multilayer capacitor 1 can be reduced. Among a plurality of first and second inner electrodes 3, 4 laminated in the opposing direction of the first and second side faces 2a, 2b, the first or second inner electrode 3, 4 at the outermost layer on the first or second side face 2a, 2b side is separated by a distance Cv from the first or second side face 2a, 2b adjacent thereto (see FIG. 4(a)).

Since each of the end faces 2e, 2f is substantially square, thus constructed multilayer capacitor 1 can attain the same mounting structure no matter which of the side faces 2a to 2d of the multilayer capacitor 1 is employed as a mounting surface, whereby the mounting operation can be made more efficient. Specifically, the multilayer capacitor 1 may be mounted to a circuit board S such that the inner electrodes 3, 4 are parallel to the circuit substrate S (the side face 2b is employed as the mounting surface) as illustrated in FIG. 4(a) or perpendicular to the circuit board S (the side face 2d is employed as the mounting surface) as illustrated in FIG. 4(b).

Though the above-mentioned multilayer capacitor mounted to the circuit board S attains the same mounting structure in appearance no matter which side face is employed as a mounting surface, its ESL value may fluctuate depending on the mounting direction. Therefore, the multilayer capacitor 1 in accordance with this embodiment further comprises the following structure for reducing the fluctuation in ESL value depending on the mounting direction.

In the above-mentioned multilayer capacitor, the distance between each inner electrode and the circuit board changes according to the mounting direction, so that the parasitic capacitance occurring between the inner electrode and circuit board varies depending on the mounting direction, whereby a difference occurs between the ESL value generated by the horizontally mounted multilayer capacitor and the ESL value generated by the vertically mounted multilayer capacitor. Therefore, taking account of the relative relationship between the distance Cv set regardless of the distance Wg in order to maximize the number of laminated layers of the inner electrodes in the multilayer capacitor and so forth and the distance Wg set regardless of the distance Cv in order to maximize the area of the inner electrodes in the multilayer capacitor and so forth, the inventor has found a relationship which suppresses the fluctuation in ESL value of the multilayer capacitor 1 as follows and applied this relationship to the structure of the multilayer capacitor 1, thereby reducing the fluctuation in ESL value.

First, for studies, “1005” and “0603” (a multilayer capacitor having a length of 0.6 mm, a height of 0.3 mm, and a width of 0.3 mm) were employed as sizes of products. Subsequently, as illustrated in FIG. 5, the relationship between the ESL value and the distance Cv in the case where the multilayer capacitor 1 was horizontally laminated was calculated, whereby the following equation (1) was obtained. Also, the relationship between the ESL value and the distance Wg in the case where the multilayer capacitor 1 was vertically laminated was calculated, whereby the following equation (2) was obtained.

[Math. 1]

ESL value(horizontal)=0.67×Cv+81.5(unit for Cv: μm) (1)

[Math. 2]

ESL value(vertical)=0.45×Wg+73.5(unit for Wg: μm) (2)

The ESL value (second inductance value) represented by the above-mentioned expression (1), which is an ESL value in the case where the first or second side face 2a, 2b of the multilayer capacitor 1 is employed as a mounting surface, is calculated according to the distance Cv. The ESL value (first inductance value) represented by the above-mentioned expression (2), which is an ESL value in the case where the third or fourth side face 2c, 2d of the multilayer capacitor 1 is employed as a mounting surface, is calculated according to the distance Wg. For attaining substantially the same ESL value regardless of the mounting direction, it is initially necessary for the distance Cv to be shorter than the distance Wg in the multilayer capacitor 1 as can be seen from FIG. 5.

The inventor further conducted studies and computed an expression in which a ratio R (aspect ratio) of the ESL value represented by the above-mentioned expression (2) to the ESL value represented by the above-mentioned expression (1) fell within the range of 0.8 to 1.2 indicating that the fluctuation in ESL value is not so large, thereby finding the relationship of the distances Wg, Cv represented by the following expression (3). Forming the multilayer capacitor 1 by setting the distances Wg, Cv so as to satisfy the expression (3) can stabilize (reduce) the fluctuation in ESL value of the multilayer capacitor 1 regardless of the mounting direction.

$$\begin{matrix}[ Math . 3 ] & \\ 0.8 \leq \frac{0.45 \times Wg + 73.5}{0.67 \times Cv + 81.5} \leq 1.2 & ( 3 )\end{matrix}$$

FIG. 6 illustrates the relationships between the ratio R and the distances Cv, Wg in the above-mentioned expression (3) in the case where each of the distances Cv, Wg was changed at intervals of 10 μm within the range of 10 to 100 μm. As can be seen from this chart, the ESL value of the multilayer capacitor 1 is considerably stabilized regardless of the mounting direction at the distances Cv, Wg where the ratio R falls within the range of 0.8 to 1.2, but fluctuates more or less depending on the mounting direction at the distances Cv, Wg where the ratio R is smaller than 0.8 or greater than 1.2. Therefore, the multilayer capacitor 1 in accordance with this embodiment is constructed such that the distances Cv, Wg satisfy the above-mentioned expression (3).

When the distance Cv is smaller than 10 μm in the multilayer capacitor 1, the lower outer layer (lowermost dielectric layer) may become so thin in a barrel step at the time of manufacturing the multilayer capacitor that the inner electrodes may be exposed, thus lowering the yield, or cracks caused by external stresses, if any, may reach the inner electrodes, thereby lowering the reliability. When the distance Cv is greater than 40 μm, on the other hand, the ratio R of the ESL value often becomes smaller than 0.8 as mentioned above, whereby the fluctuation in ESL value is likely to become greater, and the number of laminated layers in the inner electrodes may decrease, thereby lowering the capacitance of the multilayer capacitor. Therefore, in the multilayer capacitor 1 in accordance with this embodiment, the inner electrodes 3, 4 and dielectric layers 10 are constructed such that the distance Cv falls within the range of 10 to 40 μm. It will be more preferred if the inner electrodes 3, 4 and the like are constructed such that the distance Cv falls within the range of 20 to 30 μm.

When the distance Wg is smaller than 40 μm in the multilayer capacitor 1, deviations in lamination of the inner electrodes at the time of manufacturing the multilayer capacitor may expose electrodes. When the distance Wg is greater than 70 μm, on the other hand, the ratio R of the ESL value often becomes greater than 1.2 as mentioned above, whereby the fluctuation in ESL value is likely to increase, and the area of the inner electrodes may decrease, thereby reducing the capacitance of the multilayer capacitor. Therefore, in the multilayer capacitor 1 in accordance with this embodiment, the inner electrodes 3, 4 are constructed such that the distance Wg falls within the range of 40 to 70 μm. It will be more preferred if the inner electrodes 3, 4 are constructed such that the distance Wg falls within the range of 50 to 70 μm.

Thus, when each side of the first and second end faces 2f, 2g has a length of 0.3 to 0.5 mm, the distance Cv is 10 to 40 μm (preferably 20 to 30 μm) while the distance Wg is 40 to 70 μm (preferably 50 to 70 μm), whereby the fluctuation in ESL value is effectively reduced in the multilayer capacitor 1.

A method of manufacturing thus constructed multilayer capacitor 1 will now be explained. The manufacturing method in accordance with this embodiment mainly comprises a first step of forming the inner electrodes 3, 4, a second step of yielding the capacitor element body 2, and a third step of forming the terminal electrodes 5, 6.

The first step of forming the inner electrodes 3, 4 forms the first inner electrode 3 on a dielectric layer 10 such that the first main electrode part 31 is separated by the distance Wg from the third and fourth side faces 2c, 2d, and the second inner electrode 4 on a dielectric layer 10 different from that mentioned above such that the second main electrode part 41 is separated by the distance Wg from the third and fourth side faces 2c, 2d. Each dielectric layer 10 is obtained, for example, by adding a binder resin, a solvent, a plasticizer, and the like to a dielectric material mainly composed of barium titanate and mixing and dispersing them, so as to prepare ceramic slurry, applying the ceramic slurry onto a support, and then drying the slurry. Each of the inner electrodes 3, 4 is fanned, for example, by applying a conductive paste which is a conductive material onto the upper face of the dielectric layer 10 by screen printing or the like and then drying it. For example, the conductive paste is a pasty composition in which a binder resin, a solvent, and the like are mixed with a metal powder such as Ni, Ag, or Pd.

Subsequently, the second step of yielding the capacitor element body 2 laminates the inner electrodes 3, 4 alternately with dielectric layer 10, so as to obtain a rectangular parallelepiped capacitor element body within which a plurality of inner electrodes 3, 4 oppose each other. In this element body, the distance Cv between the first or second inner electrode 3, 4 at the outermost layer on each of the first and second side face 2a, 2b sides and the first or second side face 2a, 2b adjacent to the inner electrode 3, 4 is made shorter than the distance Wg between the first or second main electrode part 31, 41 and the third or fourth side face 2c, 2d. The rectangular parallelepiped element body is heated, dried, debindered, burned, barrel-polished, and so forth, whereby the capacitor element body 2 is obtained.

Next, the third step of forming the capacitor element body 2 with the terminal electrodes 5, 6 forms the first terminal electrode 5 such that the part of the first to fourth side faces 2a to 2d on the first end face 2e side and substantially the whole surface of the first end face 2e are covered therewith. The first terminal electrode 5 is formed with an electrode width W1 as a width in the opposing direction of the first and second end faces 2e, 2f. This connects the first terminal electrode 5 to the first lead electrode parts 32 and the like exposed at the third and forth side faces 2c, 2d. Similarly, the second terminal electrode 6 is formed so as to cover the part of the first to fourth side faces 2a to 2d on the second end face 2f side and substantially the whole surface of the second end face 2f. The second terminal electrode 6 is formed with an electrode width W2 as a width in the opposing direction of the first and second end faces 2e, 2f. This connects the second terminal electrode 6 to the second lead electrode parts 42 and the like exposed at the third and forth side faces 2c, 2d. When forming the first and second terminal electrodes 5, 6, the distance G between the terminal electrodes 5, 6 is made shorter than that of each of the electrode widths W1, W2. Each of the terminal electrodes 5, 6 is formed by transferring a conductive paste containing a conductive metal powder mainly composed of Ag, Cu, or Ni and glass fit onto the capacitor element body 2.

As mentioned above, the first and second steps form the first and second inner electrodes 3, 4 such that the distance Cv between the first or second inner electrode 3, 4 at the outermost layer on each of the first and second side face 2a, 2b sides and the first or second side face 2a, 2b adjacent to the inner electrode 3, 4 is made shorter than the distance Wg between the first or second main electrode part 31, 41 and the third or fourth side face 2c, 2d and laminate the inner electrodes 3, 4 alternately with the dielectric layer 10. Further, the distances Wg and Cv are set such that the ratio of the ESL value (see the above-mentioned expression (2)) in the case where the third or fourth side face 2c, 2d of the multilayer capacitor 1 is employed as the mounting surface, calculated according to the distance Wg, to the ESL value (see the above-mentioned expression (1)) in the case where the first or second side faces 2a, 2b of the multilayer capacitor 1 is employed as the mounting surface, calculated according to the distance Cv, falls within the range of 0.8 to 1.2 as represented by the above-mentioned expression (3), whereby the multilayer capacitor 1 is manufactured.

In the multilayer capacitor 1 in accordance with this embodiment, as in the foregoing, the distance Cv corresponding to the distance between the inner electrode 3, 4 and the circuit board S in the case where the mounting direction is such that the inner electrode 3, 4 and the circuit board S are parallel to each other is shorter than the distance Wg corresponding to the distance between the inner electrode 3, 4 and the circuit board S in the case where the mounting direction is such that the inner electrode 3, 4 and the circuit board S intersect. This can reduce the difference between the ESL value generated by the horizontally mounted multilayer capacitor 1 and the ESL value generated by the vertically mounted multilayer capacitor 1. As a result, the multilayer capacitor 1 in accordance with the present invention can be mounted to the circuit board S or the like while using any of the side faces 2a to 2d as the mounting surface without taking account of the fluctuation in ESL value and can improve the mounting efficiency. In addition, since the first and second lead electrode parts 32, 42 are constructed so as to extend to the side faces 2c, 2d, the respective currents flowing through the lead electrode parts are directed opposite to each other, so that their magnetic fields cancel each other out, whereby the ESL value itself can be reduced. Also, the distance G between the first and second terminal electrodes 5, 6 is shorter than each of the electrode widths W1, W2 of the terminal electrodes 5, 6 and thus can further lower the ESL value.

The distances Wg and Cv are set such that the ratio of the ESL value (see the above-mentioned expression (2)) in the case where the third or fourth side face 2c, 2d of the multilayer capacitor 1 is employed as the mounting surface, calculated according to the distance Wg, to the ESL value (see the above-mentioned expression (1)) in the case where the first or second side faces 2a, 2b is employed as the mounting surface, calculated according to the distance Cv, falls within the range of 0.8 to 1.2 as represented by the above-mentioned expression (3). This further reduces the fluctuation in ESL value depending on the mounting direction of the multilayer capacitor 1.

When each side of the first and second end faces 2e, 2f has a length of 0.3 to 0.5 mm in the multilayer capacitor 1, the distance Cv is 10 to 40 μm while the distance Wg is 40 to 70 μm. More preferably, the distance Cv is 20 to 30 μm while the distance Wg is 50 to 70 μm. These can further reduce the fluctuation in ESL value. In addition, since the lower limit of the distance Cv is 10 μm, the possibility of cracks caused by stresses exerted on the multilayer capacitor exposing the inner electrodes to the surface is reduced, for example. Since the upper limit of the distance Cv is 40 μm, the number of laminations of inner electrodes in the multilayer capacitor can be increased. Since the lower limit of the distance Wg is 40 μm, the possibility of the main electrode parts being exposed to the side faces because of positional deviations at the time of laminating the inner electrodes can be reduced. Since the upper limit of the distance Wg is 70 μm, the area of the main electrode parts can be increased.

An example of a mounting structure for mounting the above-mentioned multilayer capacitor 1 to the circuit board S will now be explained with reference to FIGS. 7 and 8.

First, the structure of the circuit board S will be explained. The circuit board S is a multilayer substrate comprising through-hole electrodes H1, H2 disposed therewithin and mounting electrodes E1, E2 formed over the surface of the circuit board S so as to be connected to the respective through-hole electrodes H1, H2 and extend outward from the through-hole electrodes H1, H2. The through-hole electrodes H1, H2 are separated from each other by a center-to-center distance shorter than that between the first and second lead electrode parts 32, 42 of the multilayer capacitor 1 mounted to the circuit board S.

Operations and effects obtained when mounting the multilayer capacitor 1 to the circuit board S while employing any of the first to fourth side faces 2a to 2d as the mounting surface and connecting the terminal electrodes 5, 6 to the mounting electrodes E1, E2 will now be explained.

When the multilayer capacitor 1 is horizontally mounted to the circuit board S as illustrated in FIG. 7, for example, a current I1 flowing from the through-hole electrode H1 to the lead electrode parts 42 through the mounting electrode E1 and a current I2 flowing through the main electrode parts 31, 41 are at least partly directed opposite to each other. Also, a current I3 flowing from the lead electrode parts 32 to the through-hole electrode H2 through the mounting electrode E2 and the current I2 flowing through the main electrode parts 31, 41 are at least partly directed opposite to each other. As a result, the respective magnetic fields produced by the currents I1 to I3 flowing through the electrodes and the like cancel each other out, whereby this mounting structure can reduce the ESL value of the multilayer capacitor 1.

When the multilayer capacitor 1 is vertically mounted to the circuit board S as illustrated in FIG. 8, the current I1 flowing from the through-hole electrode H1 to the lead electrode parts 42 through the mounting electrode E1 and the current I2 flowing through the main electrode parts 31, 41 are at least partly directed opposite to each other. Also, the current I3 flowing from the lead electrode parts 32 to the through-hole electrode H2 through the mounting electrode E2 and the current I2 flowing through the main electrode parts 31, 41 are at least partly directed opposite to each other. As a result, the respective magnetic fields produced by the currents I1 to I3 flowing through the electrodes and the like cancel each other out, whereby this mounting structure can reduce the ESL value of the multilayer capacitor 1. In other words, regardless of the mounting direction, this mounting structure can reduce the ESL value of the multilayer capacitor 1 and, as mentioned above, can inhibit the ESL value from fluctuating.

Though a preferred embodiment of the present invention has been explained in detail in the foregoing, the present invention can be modified in various ways without being restricted to the above-mentioned embodiment. For example, the above-mentioned first and second inner electrodes 3, 4 and first and second terminal electrodes 5, 6 may be modified as follows.

The first and second inner electrodes 3, 4 may be modified like inner electrodes 3a, 4a illustrated in FIG. 9, for example. The modified example illustrated in FIG. 9 differs from the above-mentioned embodiment in terms of electrode parts 33a, 43a of the first and second inner electrodes 3a, 4a. The electrode parts 33a, 43a do not extend to the first or second end face 2e, 2f so as to be exposed there like the third and fourth lead electrode parts 33, 43, but are kept from being connected to the first and second terminal electrodes 5, 6. This structure allows all the currents to flow through the first and second lead electrode parts 32, 42 and thus can increase areas where the currents are directed opposite to each other, so as to reduce the ESL value by causing the magnetic fields to cancel each other out.

The first and second inner electrodes 3, 4 may also be modified like inner electrodes 3b, 4b illustrated in FIG. 10, for example. The modified example illustrated in FIG. 10 differs from the above-mentioned embodiment in terms of third and fourth lead electrode parts 33b, 43b of the first and second inner electrodes 3b, 4b. The lead electrode parts 33b, 43b are formed continuous with not only the end portions of the first and second main electrode parts 31, 41, but also end portions of the second and fourth lead electrode parts 32, 42. This structure increases the area by which the lead electrodes are connected to the terminal electrodes 5, 6 and thus can reduce the equivalent series resistance.

The first and second terminal electrodes 5, 6 may be modified like terminal electrodes 5a, 6a illustrated in FIG. 11, for example. In the modified example illustrated in FIG. 11, the first terminal electrode 5a covers only the part of the first to fourth side faces 2a to 2d on the first end face 2e side, but not the first end face 2e. The second terminal electrode 6a covers only the part of the first to fourth side faces 2a to 2d on the second end face 2f side, but not the second end face 2f. In this case, no inner electrodes are exposed at the end faces 2e, 2f, while the terminal electrodes 5a, 6a are connected to the inner electrodes 3, 4 through the first or second lead electrode parts 32, 42. This structure forms no terminal electrodes on the end faces 2e, 2f and thus can make the multilayer capacitor 1 shorter in length or stabilized accordingly.

What is claimed is:

1. A multilayer capacitor comprising:
a capacitor element body having first and second side faces, each having a substantially rectangular form, opposing each other, third and fourth side faces extending in a longer side direction of the first and second side faces so as to connect the first and second side faces to each other and opposing each other, and substantially square first and second end faces extending in a shorter side direction of the first and second side faces so as to connect the first and second side faces to each other and opposing each other, the capacitor element body being constituted by a plurality of dielectric layers laminated in the opposing direction of the first and second side faces;
a first inner electrode disposed within the capacitor element body, the first inner electrode having a first lead electrode part extending to the third and fourth side faces and a first main electrode part separated by a distance Wg from the third and fourth side faces;
a second inner electrode disposed within the capacitor element body, the second inner electrode having a second lead electrode part extending to the third and fourth side faces and a second main electrode part opposing the first main electrode part in the opposing direction of the first and second side faces and separated by the distance Wg from the third and fourth side faces;
a first terminal electrode disposed on the first end face side of the first, second, third, and fourth side faces each with an electrode width W1 as a width in the opposing direction of the first and second end faces and connected to the first lead electrode part; and
a second terminal electrode disposed on the second end face side of the first, second, third, and fourth side faces each with an electrode width W2 as a width in the opposing direction of the first and second end faces while being separated from the first terminal electrode by a distance G shorter than each of the electrode widths W1 and W2 and connected to the second lead electrode part;
wherein the first and second inner electrodes are alternately laminated with a dielectric layer of the plurality of dielectric layers in between in the opposing direction of the first and second side faces, while the first or second inner electrode at the outermost layer on each of the first and second side face sides and the first or second side face adjacent to the inner electrode have a distance Cv therebetween shorter than the distance Wg between the first or second main electrode part and the third or fourth side face.

2. A multilayer capacitor according to claim 1, wherein the distances Wg and Cv are set such that a ratio of a first inductance value calculated according to the distance Wg as an equivalent series inductance value obtained when the third or fourth side face of the multilayer capacitor is used as a mounting surface to a second inductance value calculated according to the distance Cv as an equivalent series inductance value obtained when the first or second side face of the multilayer capacitor is used as a mounting surface falls within the range of 0.8 to 1.2.

3. A multilayer capacitor according to claim 1, wherein each side of the first and second end faces has a length of 0.3 to 0.5 mm, the distance Cv is 10 to 40 μm, and the distance Wg is 40 to 70 μm.

4. A multilayer capacitor according to claim 3, wherein the distance Cv is 20 to 30 μm, and the distance Wg is 50 to 70 μm.

5. A mounting structure for mounting the multilayer capacitor according to claim 1 to a circuit board,
the circuit board comprising through-hole electrodes formed in the circuit board so as to be separated from each other by a distance shorter than that between the first and second lead electrode parts in the opposing direction of the first and second end faces, and mounting electrodes formed on the circuit board so as to be connected to the respective through-hole electrodes and extend outward from the through-hole electrodes;
the mounting structure connecting the first and second terminal electrodes of the multilayer capacitor to the respective mounting electrodes by using one of the first, second, third, and fourth side faces as a mounting surface.

6. A method of manufacturing a multilayer capacitor comprising a capacitor element body having first and second side faces, each having a substantially rectangular form, opposing each other, third and fourth side faces extending in a longer side direction of the first and second side faces so as to connect the first and second side faces to each other and opposing each other, and substantially square first and second end faces extending in a shorter side direction of the first and second side faces so as to connect the first and second side faces to each other and opposing each other; first and second inner electrodes disposed within the capacitor element body; and first and second terminal electrodes disposed on a surface of the capacitor element body;
the method comprising the steps of:
forming the first and second inner electrodes on respective dielectric layers;
laminating the first and second inner electrodes alternately with a dielectric layer in between, so as to yield a capacitor element body having the first and second inner electrodes arranged therewithin; and
forming the first and second terminal electrodes on the capacitor element body;
wherein the step of forming the first and second inner electrodes forms the first and second inner electrodes such that the first inner electrode has a first lead electrode part extending to the third and fourth side faces and a first main electrode part separated by a distance Wg from the third and fourth side faces and the second inner electrode has a second lead electrode part extending to the third and fourth side faces and a second main electrode part separated by the distance Wg from the third and fourth side faces;
wherein the step of forming the first and second terminal electrodes forms the first terminal electrode disposed on the first end face side of the first, second, third, and fourth side faces each with an electrode width W1 as a width in the opposing direction of the first and second end faces and connected to the first lead electrode part, and the second terminal electrode disposed on the second end face side of the first, second, third, and fourth side faces each with an electrode width W2 as a width in the opposing direction of the first and second end faces while being separated from the first terminal electrode by a distance G shorter than each of the electrode widths W1, W2 and connected to the second lead electrode part; and
wherein the steps of forming the first and second inner electrodes and yielding the capacitor element body manufacture the multilayer capacitor by laminating the first and second inner electrodes alternately with the dielectric layer in between such that the first or second inner electrode at the outermost layer on each of the first and second side face sides and the first or second side face adjacent to the inner electrode have a distance Cv therebetween shorter than the distance Wg between the first or second main electrode part and the third or fourth side face, and setting the distances Wg and Cv such that a ratio of a first inductance value calculated according to the distance Wg as an equivalent series inductance value obtained when the third or fourth side face of the multilayer capacitor is used as a mounting surface to a second inductance value calculated according to the distance Cv as an equivalent series inductance value obtained when the first or second side face of the multilayer capacitor is used as a mounting surface falls within the range of 0.8 to 1.2.
